(19) United States
(12) Patent Application Publication
(10) Pub. No.: US 2023/0309404 A1
(43) Pub. Date: Sep. 28, 2023

(54) SYSTEM AND METHOD FOR REGULATING THE TEMPERATURE OF AN INKJET PRINTHEAD DURING DUPLEX PRINTING OPERATIONS

(71) Applicant: Xerox Corporation, Norwalk, CT (US)

(72) Inventors: Douglas K. Herrmann, Webster, NY (US); Jason M. LeFevre, Penfield, NY (US); Seemit Praharaj, Webster, NY (US); Chu-Heng Liu, Penfield, NY (US); Jorge A. Alvarez, Webster, NY (US)

(21) Appl. No.: 17/656,404

(22) Filed: Mar. 24, 2022

(51) Int. Cl. H01L 35/28; B41J 2/045; H01L 35/12

(52) U.S. Cl. CPC H01L 35/28; B41J 2/04563; B41J 2/04581; H01L 35/12

(57) ABSTRACT

An inkjet printer includes a pair of temperature regulation modules mounted on opposite sides of each printhead in the printer. Each temperature regulation module includes a thermoelectric cooling device that is activated by a controller when the temperature of the printhead exceeds a predetermined setpoint. By cooling the printheads, the temperature of the printheads can be kept in a temperature range that enables fast drying inks to obtain their optimal performance and that prevents duplex printing operations from raising the temperature of the printheads significantly above the predetermined setpoint.

### TECHNICAL FIELD

This disclosure relates generally to devices that produce ink images on media, and more particularly, to the regulation of printhead temperatures in such devices during printing.

### BACKGROUND

Inkjet imaging devices, also known as inkjet printers, eject liquid ink from printheads to form images on an image receiving surface. The printheads include a plurality of inkjets that are arranged in an array. Each inkjet has a piezoelectric actuator that is coupled to a printhead controller. The printhead controller generates firing signals that correspond to digital data content corresponding to images. The actuators in the printheads respond to the firing signals by expanding into an ink chamber to eject ink drops onto an image receiving surface and form an ink image that corresponds to the digital image content used to generate the firing signals. The image receiving surface is usually a continuous web of media material or a series of media sheets.

Inkjet printers used for producing color images typically include multiple printhead assemblies. Each printhead assembly includes one or more printheads that typically eject a single color of ink. In a typical inkjet color printer, four printhead assemblies are positioned in a process direction with each printhead assembly ejecting a different color of ink. The four ink colors most frequently used are cyan, magenta, yellow, and black. The common nomenclature for such printers is CMYK color printers. Some CMYK printers have two printhead assemblies that print each color of ink. The printhead assemblies that print the same color of ink are offset from each other by one-half of the distance between adjacent inkjets in the cross-process direction to double the number of pixels per inch density of a line of the color of ink ejected by the printheads in the two assemblies. As used in this document, the term “process direction” means the direction of movement of the image receiving surface as it passes the printheads in the printer and the term “cross-process direction” means a direction that is perpendicular to the process direction in the plane of the image receiving surface.

Image quality in color inkjet printers depends upon at least three parameters: color gamut, graininess, and ink drop satellites. Color gamut can be addressed by using inks that dry faster. The faster drying inks allow more ink to be deposited in the image. The dryers also evaporate the ink more quickly so more ink volume can be dispensed on the media without the ink offsetting to rollers moving the media through the printer.

Graininess, and more specifically overlay graininess, can also be addressed by faster drying inks because the ink drops adhere to the media more quickly so they are immobilized faster. The primary cause of overlay graininess is shear force acting on the ink drops, which increases wet-drop-on-wet-drop interaction that intermixes the ink drops with one another. Thus, decreased mobilization reduces the ink drop interaction and, consequently, overlay graininess. The best overlay graininess performance of some faster drying inks is achieved when the printhead temperature setpoint changes from a current target of 37° C. to a lower temperature of 32° C. Additionally, the stability of the inkjets ejecting the faster drying ink is more robust when the printhead temperature is maintained in a range of about 30° C. to about 32° C. Maintaining printhead temperature in this range is very difficult when heavyweight media stocks are duplex printed because the heavyweight stock absorbs heat as the sheets pass the printheads and are returned to the print zone for duplex printing. Some of this absorbed heat is transferred to the printheads, which raises the temperature of the printheads. The increase in printhead temperature adversely affects the optimal performance of the faster drying inks and can lead to the ink drying on the nozzle plate and in the nozzles. Dry ink on the nozzle plate and in the nozzles leads to inoperative inkjets. As used in this document, the term “inoperative inkjet” means inkjets that do not eject ink drops at all or inkjets that eject ink drops in a direction away from the normal between an inkjet nozzle and the ink receiving surface. Preserving the effectiveness of quick drying inks by regulating printhead temperatures in an effective range for the ink would be beneficial.

### SUMMARY

A color inkjet printer is configured to regulate printhead temperature, especially during heavyweight stock duplex printing. The color inkjet printer includes a printhead configured to eject drops of ink, a sensor configured to generate a signal indicative of a temperature of the printhead, a first thermoelectric cooling device configured to remove heat from the printhead, and a controller operatively connected to the sensor and the first cooling device. The controller is configured to operate the first cooling device to remove heat from the printhead in response to the signal generated by the sensor indicating the temperature of the printhead is greater than a predetermined temperature setpoint.

A method of operating a color inkjet printer regulates printhead temperature, especially during heavyweight stock duplex printing. The method includes generating a signal indicative of a temperature of a printhead in the inkjet printer, comparing the generated signal to a predetermined temperature setpoint, and operating a first thermoelectric cooling device to remove heat from the printhead in response to the signal generated by the sensor indicating the temperature of the printhead is greater than the predetermined temperature setpoint.

A thermal regulation module is configured to be selectively mounted to and removed from a printhead in a color inkjet printer to regulate printhead temperature. The thermal regulation module includes a bracket, a first thermal conductive member mounted to the bracket, and a first thermoelectric cooling device mounted to the first thermal conductive member, the first thermoelectric cooling device being configured to remove heat from the first thermal conductive member.

A printhead is configured for regulation of the printhead temperature in a color inkjet printer. The printhead includes a printhead having a plurality of inkjets, each inkjet being configured with a piezoelectric transducer to eject ink drops, a thermal conductive member mounted to a first side of the printhead, and a thermoelectric cooling device mounted to the thermal conductive member, the configured to remove heat from the thermal conductive member.

### BRIEF DESCRIPTION OF THE DRAWINGS

The foregoing aspects and other features of a color inkjet printer and color inkjet printer operational method that regulates printhead temperature are explained in the following description, taken in connection with the accompanying drawings.

FIG. 1 is a schematic drawing of a color inkjet printer that regulates printhead temperatures.

FIG. 2A is a cross-sectional side view of a printhead configured with a pair of temperature regulation modules in the printer shown in FIG. 1.

FIG. 2B is a perspective view of a replaceable temperature regulation module mounted about a printhead.

FIG. 3 is a block diagram of the components in the printer of FIG. 1 that regulate the temperature of a printhead in the printer.

FIG. 4 is a flow diagram of a process for operating the temperature regulation module of FIG. 1.

FIG. 5 is a schematic drawing of a prior art color inkjet printer that is unable to maintain printhead temperature in a range effective for the use of faster drying inks with heavyweight stock during duplex printing.

FIG. 6 depicts the print zone in the printer of FIG. 5.

### DETAILED DESCRIPTION

For a general understanding of the environment for the printer and the printer operational method disclosed herein as well as the details for the printer and the printer operational method, reference is made to the drawings. In the drawings, like reference numerals have been used throughout to designate like elements. As used herein, the word “printer” encompasses any apparatus that ejects ink drops onto different types of media to form ink images.

The printer and method described below uses a thermoelectric cooling device on both sides of a piezoelectric printhead in the process direction to remove heat from the piezoelectric printhead when the printhead temperature goes outside a predetermined range. By setting the upper threshold of the range to 32° C. and the lower threshold to 30° C., the printhead temperature can be maintained in a range that ensures optimal performance of most fast drying inks and that helps preserve the operational status of the piezoelectric inkjets in the printhead, especially during duplex print jobs using heavyweight stocks.

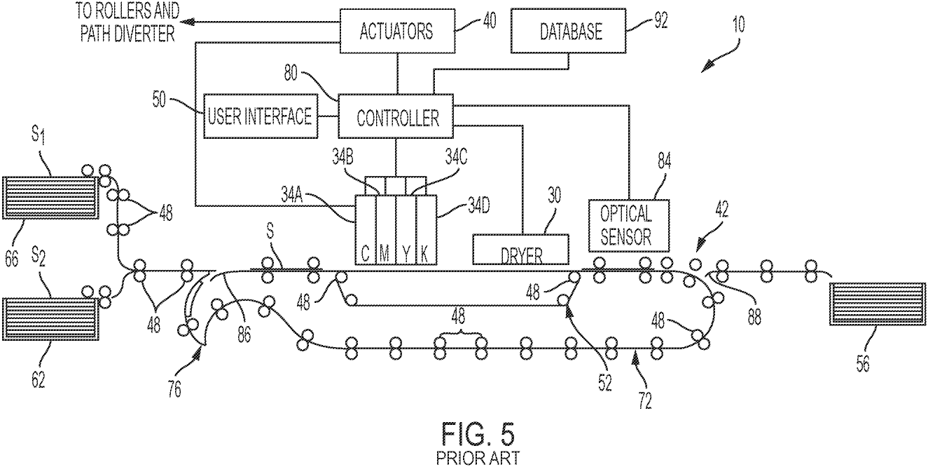

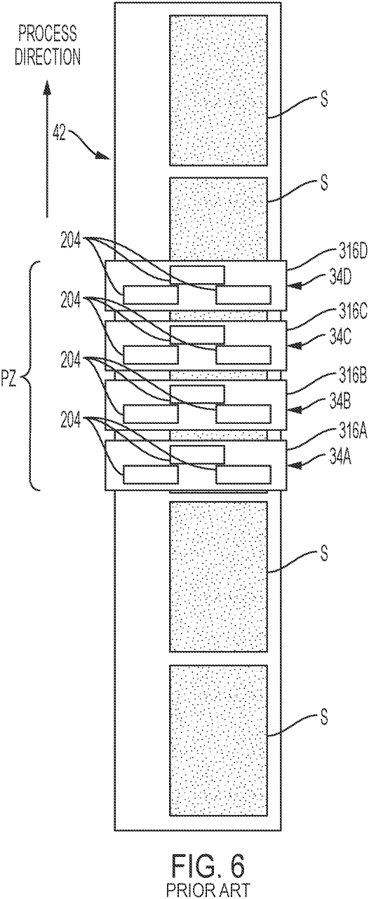

FIG. 5 depicts a prior art high-speed color inkjet printer 10 that does not cool the piezoelectric printheads of the printer. As illustrated, the printer 10 is a printer that directly forms an ink image on a surface of a media sheet stripped from one of the supplies of media sheets S₁ or S₂ and the sheets S are moved through the printer 10 by the controller 80 operating one or more of the actuators 40 that are operatively connected to rollers or to at least one driving roller of conveyor 52 that comprise a portion of the media transport 42 that passes through the print zone PZ (shown in FIG. 6) of the printer. In one embodiment, each printhead module has only one printhead that has a width that corresponds to a width of the widest media in the cross-process direction that can be printed by the printer. In other embodiments, the printhead modules have a plurality of printheads with each printhead having a width that is less than a width of the widest media in the cross-process direction that the printer can print. In these modules, the printheads are arranged in an array of staggered printheads that enables media wider than a single printhead to be printed. Additionally, the printheads within a module or between modules can also be interlaced so the density of the drops ejected by the printheads in the cross-process direction can be greater than the smallest spacing between the inkjets in a printhead in the cross-process direction. Although printer 10 is depicted with only two supplies of media sheets, the printer can be configured with three or more sheet supplies, each containing a different type or size of media.

The print zone PZ in the prior art printer 10 of FIG. 5 is shown in FIG. 6. The print zone PZ has a length in the process direction commensurate with the distance from the first inkjets that a sheet passes in the process direction to the last inkjets that a sheet passes in the process direction and it has a width that is the maximum distance between the most outboard inkjets on opposite sides of the print zone that are directly across from one another in the cross-process direction. Each printhead module 34A, 34B, 34C, and 34D shown in FIG. 6 has three printheads 204 mounted to one of the printhead carrier plates 316A, 316B, 316C, and 316D, respectively.

As shown in FIG. 5, the printed image passes under an image dryer 30 after the ink image is printed on a sheet S. The image dryer 30 can include an infrared heater, a heated air blower, air returns, or combinations of these components to heat the ink image and at least partially fix an image to the web. An infrared heater applies infrared heat to the printed image on the surface of the web to evaporate water or solvent in the ink. The heated air blower directs heated air using a fan or other pressurized source of air over the ink to supplement the evaporation of the water or solvent from the ink. The air is then collected and evacuated by air returns to reduce the interference of the dryer air flow with other components in the printer.

A duplex path 72 is provided to receive a sheet from the transport system 42 after a substrate has been printed and move it by the rotation of rollers in an opposite direction to the direction of movement past the printheads. At position 76 in the duplex path 72, the substrate can be turned over so it can merge into the job stream being carried by the media transport system 42. The controller 80 is configured to flip the sheet selectively. That is, the controller 80 can operate actuators to turn the sheet over so the reverse side of the sheet can be printed or it can operate actuators so the sheet is returned to the transport path without turning over the sheet so the printed side of the sheet can be printed again. Movement of pivoting member 88 provides access to the duplex path 72. Rotation of pivoting member 88 is controlled by controller 80 selectively operating an actuator 40 operatively connected to the pivoting member 88. When pivoting member 88 is rotated counterclockwise as shown in FIG. 5, a substrate from media transport 42 is diverted to the duplex path 72. Rotating the pivoting member 88 in the clockwise direction from the diverting position closes access to the duplex path 72 so substrates on the media transport move to the receptacle 56. Another pivoting member 86 is positioned between position 76 in the duplex path 72 and the media transport 42. When controller 80 operates an actuator to rotate pivoting member 86 in the counterclockwise direction, a substrate from the duplex path 72 merges into the job stream on media transport 42. Rotating the pivoting member 86 in the clockwise direction closes the duplex path access to the media transport 42.

As further shown in FIG. 5, the printed media sheets S not diverted to the duplex path 72 are carried by the media transport to the sheet receptacle 56 in which they are be collected. Before the printed sheets reach the receptacle 56, they pass by an optical sensor 84. The optical sensor 84 generates image data of the printed sheets and this image data is analyzed by the controller 80. The controller 80 is configured to detect streakiness in the printed images on the media sheets of a print job. Additionally, sheets that are printed with test pattern images are inserted at intervals during the print job. These test pattern images are analyzed by the controller 80 to determine which inkjets, if any, that were operated to eject ink into the test pattern did in fact do so, and if an inkjet did eject an ink drop whether the drop landed at its intended position with an appropriate mass. Any inkjet not ejecting an ink drop it was supposed to eject or ejecting a drop not having the right mass or landing at an errant position is called an inoperative inkjet in this document. The controller can store data identifying the inoperative inkjets in database 92 operatively connected to the controller. These sheets printed with the test patterns are sometimes called run-time missing inkjet (RTMJ) sheets and these sheets are discarded from the output of the print job. A user can operate the user interface 50 to obtain reports displayed on the interface that identify the number of inoperative inkjets and the printheads in which the inoperative inkjets are located. The optical sensor 84 can be a digital camera, an array of LEDs and photodetectors, or other devices configured to generate image data of a passing surface. As already noted, the media transport also includes a duplex path that can turn a sheet over and return it to the transport prior to the printhead modules so the opposite side of the sheet can be printed. While FIG. 5 shows the printed sheets as being collected in the sheet receptacle, they can be directed to other processing stations (not shown) that perform tasks such as folding, collating, binding, and stapling of the media sheets.

Operation and control of the various subsystems, components and functions of the machine or printer 10 are performed with the aid of a controller or electronic subsystem (ESS) 80. The ESS or controller 80 is operatively connected to the components of the printhead modules 34A - 34D (and thus the printheads), the actuators 40, and the dryer 30. The ESS or controller 80, for example, is a self-contained computer having a central processor unit (CPU) with electronic data storage, and a display or user interface (UI) 50. The ESS or controller 80, for example, includes a sensor input and control circuit as well as a pixel placement and control circuit. In addition, the CPU reads, captures, prepares, and manages the image data flow between image input sources, such as a scanning system or an online or a work station connection (not shown), and the printhead modules 34A-34D. As such, the ESS or controller 80 is the main multi-tasking processor for operating and controlling all of the other machine subsystems and functions, including the printing process.

The controller 80 can be implemented with general or specialized programmable processors that execute programmed instructions. The instructions and data required to perform the programmed functions can be stored in memory associated with the processors or controllers. The processors, their memories, and interface circuitry configure the controllers to perform the operations described below. These components can be provided on a printed circuit card or provided as a circuit in an application specific integrated circuit (ASIC). Each of the circuits can be implemented with a separate processor or multiple circuits can be implemented on the same processor. Alternatively, the circuits can be implemented with discrete components or circuits provided in very large scale integrated (VLSI) circuits. Also, the circuits described herein can be implemented with a combination of processors, ASICs, discrete components, or VLSI circuits.

In operation, image content data for an image to be produced are sent to the controller 80 from either a scanning system or an online or work station connection for processing and generation of the printhead control signals output to the printhead modules 34A-34D. Along with the image content data, the controller receives print job parameters that identify the media weight, media dimensions, print speed, media type, ink area coverage to be produced on each side of each sheet, location of the image to be produced on each side of each sheet, media color, media fiber orientation for fibrous media, print zone temperature and humidity, media moisture content, and media manufacturer. As used in this document, the term “print job parameters” means non-image content data for a print job and the term “image content data” means digital data that identifies an ink image to be printed on a media sheet.

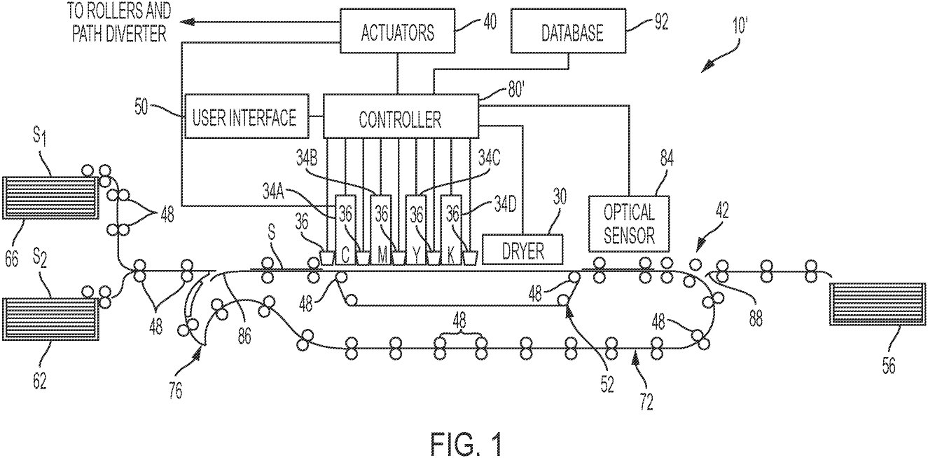

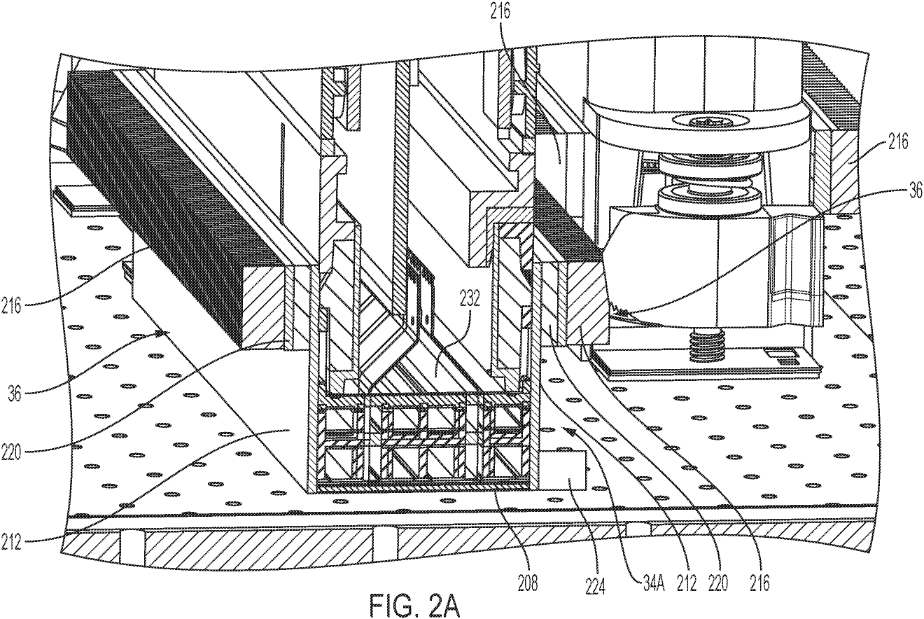

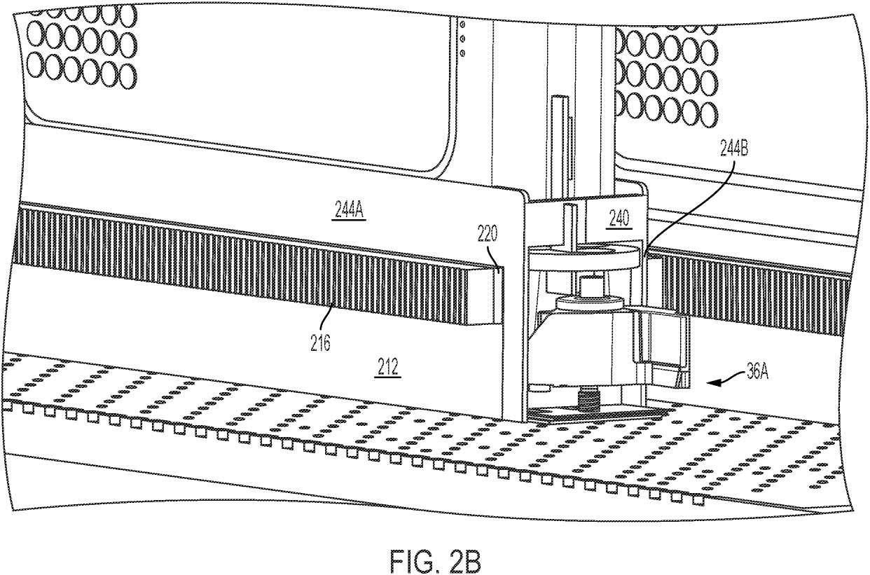

Using like reference numbers to identify like components, FIG. 1 depicts a high-speed color inkjet printer 10′ in which printhead temperature regulation modules 36 are monitored and operated by the controller 80′ to regulate the temperature of each piezoelectric printhead in the printer. A piezoelectric printhead 34A₁ is configured with a pair of modules 36 as shown in FIG. 2A and the heat sink 216 of another module 36 associated with the middle printhead in the same printhead module 34A (FIG. 6) also appears in FIG. 2A. The printhead can be configured with the thermal conductive member 212 and the thermoelectric cooling device 220, and optionally a heat sink 216, as an integral replaceable unit or the conductive member, cooling device, and optionally the heat sink can be mounted as described to a printhead in an existing printer. Such a modification of a previously known printer also requires the installation of a printhead temperature sensor, if one is not already in the printer for each printhead, and additional programmed instructions stored in a member operatively connected to the controller so the controller can operate the temperature regulations module as described in more detail below. In FIG. 1, the depicted modules 36 assist in the temperature regulation of the printheads closest to the viewer in each printhead module 34A, 34B, 34C, and 34D. The modules 36 are configured for use with piezoelectric printheads rather than thermal inkjet printheads because regulating the temperature of a piezoelectric inkjet printhead within a narrow temperature range below its normal operating temperature, especially during duplex print jobs using heavyweight stock, requires more precision than thermal printheads in which each inkjet includes a heater.

A piezoelectric printhead 36A configured with a temperature regulation module 36 is shown in more detail in FIG. 2A. In FIG. 2A, a module 36 is positioned on each side of the printhead 34A₁ in the process direction. Each module includes a heat conductive member 212, a heat sink 216, which is depicted as a set of heat fins, and a thermoelectric cooling device 220 interposed between the heat conductive member 212 and the heat fins 216. The conductive member 212 is made of a material having a high thermal conductivity, such as copper (385 Watts/meter-Kelvin degree) or aluminum (239 Watts/meter-Kelvin degree). The heat fins 216 are also made of a relatively high thermally conductive material, such as aluminum (237 Watts/meter-Kelvin degree). As used in this document, the term “thermoelectric cooling device” means a device that transmits heat along a thermal gradient in the device in the direction of an electrical current across the device. The thermoelectric cooling device 220 is configured with a planar surface that corresponds to the planar surface from which the heat fins extend. In one embodiment, the thermoelectric cooling device is a semiconductor device that includes N and P doped regions that are configured to conduct heat in a direction that corresponds to the direction of an electrical current passing through the device. Such devices are commonly known as peltier devices and are commercially available. The controller 80′ is configured to couple an electrical current to thermoelectric cooling device 220 in a direction that causes the device to direct heat from the conductive member 212 to the heat fins 216 so the heat can be dissipated. Thus, the module 36 is configured to pull heat from the printhead 34A₁ to cool the printhead.

As shown in FIG. 2A, a temperature sensor 224 is mounted to the conductive member 212 and this sensor is operatively connected to the controller 80′. The sensor 224 is configured to generate an electrical signal indicative of the temperature of the member 212, which corresponds to the temperature of the printhead. The controller 80′ is configured with a pair of temperature setpoints that are compared to the signal from the sensor 224 to determine what type of temperature regulation is required to keep the printhead within the temperature range defined by the two setpoints as described in more detail below.

In one embodiment, the temperature regulation module 36 is configured as a replaceable module that can be selectively mounted and removed from a printhead. Such a module is shown in FIG. 2B. The module 36 includes a bracket 240 to which the heat conductive member 212 is mounted and the thermoelectric cooling device 220 is mounted to the heat conductive member 212. In the depicted embodiment, the bracket 240 is configured in a U-shape with two parallel sides 244A and 244B when viewed from the side. Each side 244A and 244B includes a thermal conductive member 212 and a thermoelectric cooling device 220 as shown in the figure. The two sides are configured with an opening between them that corresponds to a width of a printhead in the process direction and a length of a printhead in the cross-process direction, such as printhead 36A. This bracket 240 can be slipped over the printhead prior to its installation in a printhead module as shown in the figure. Other configurations of the bracket are possible, such as rectangular shape with an opening that corresponds to the shape and size of the printhead so the printhead can be inserted into the bracket and the components mounted to it. If desired, a heat sink 216, which is depicted as a set of heat fins, can also be mounted to the thermoelectric cooling device 220 using a thermally conductive adhesive similar to the adhesive used to mount the heat conductive member 212 to the bracket 240 and the one used to mount the thermoelectric cooling device 220 to the member 212. One example of such an adhesive is Dow DOWSIL™ 1-4174 TC Thermally Conductive Adhesive.

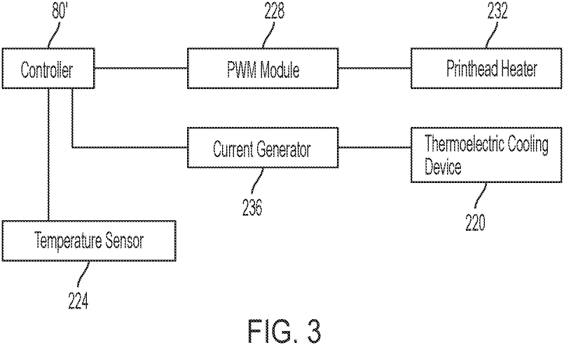

Temperature regulation of a printhead is now described with reference to FIG. 3. The controller 80′ is configured with programmed instructions stored in a memory operatively connected to the controller so when the controller 80′ executes the temperature regulation process described with reference to FIG. 3. The controller 80′ monitors the signal from the temperature sensor 224 and compares it to the upper threshold setpoint for a predetermined temperature range and a lower threshold setpoint for the range. If the temperature indicated by the signal is less than the lower threshold of the range, then the controller operates a pulse width modulation (PWM) unit 228 that is operatively connected to a printhead heater 232. The duty cycle of the PWM signal generated by the unit 228 operates the printhead heater to apply heat to the printhead. A zero percent PWM signal turns the heater off, a 100% signal turns the heater to its maximum heat producing capability, and in between these values, the heater is operated at a corresponding percentage of its maximum capability. These types of heaters are known for ensuring a printhead remains at a temperature above the ambient temperature in the printer. As the temperature signal indicates the temperature of the printhead is within the temperature range between the two set points but is increasing, the controller 80′ operates the PWM unit to reduce the heat produced by the printhead heater 232. If the temperature of the printhead exceeds the upper threshold identified by the greater of the two setpoints, then the controller sets the duty cycle of the PWM unit to zero and the controller 80′ operates the current generator 236 to send a current through the thermoelectric cooling device 220. The operation of the thermoelectric cooling device continues until the temperature indicated by the sensor signal falls below the greater setpoint and as the indicated temperature continues to fall, the controller turns off the current generator 236 and begins to operate the PWM unit 228 to increasingly turn on the heater 232 until the temperature begins to stabilize with the temperature range between the two setpoints. At that point, the controller changes the PWM signal duty cycle to keep the temperature in the temperature range. If the temperature falls out of the range, then the controller operates the cooling device 220 to reduce the temperature of the printhead if the temperature exceeds the upper temperature threshold or it operates the PWM module to generate a PWM signal with a 100% duty cycle to heat the printhead and return it to the temperature range between the setpoints. In one embodiment, the two setpoints are about 30° C. to about 32° C.

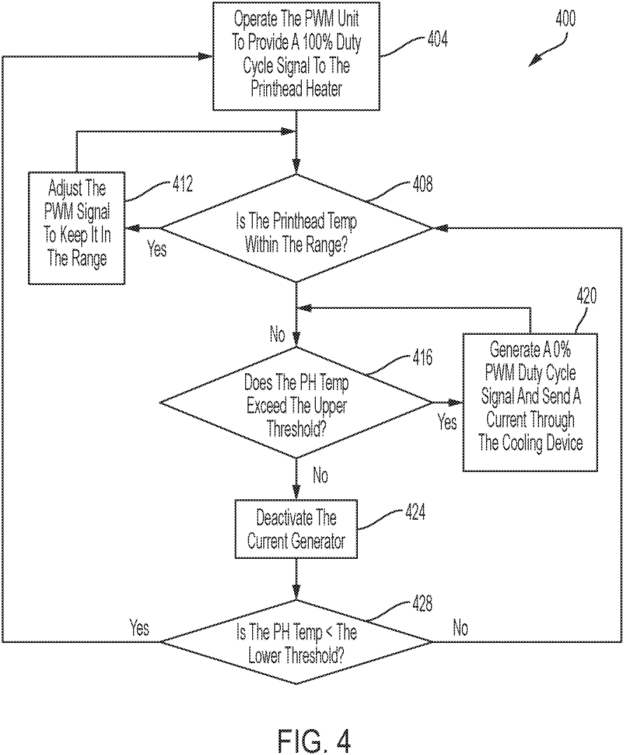

FIG. 4 depicts a flow diagram for a process 400 that regulates printhead temperature with a regulation module 36 on each side of a printhead in the process direction. The modules 36 operate to maintain the temperature of the printheads in the printer within a predetermined temperature range. In the discussion below, a reference to the process 400 performing a function or action refers to the operation of a controller, such as controller 80′, to execute stored program instructions to perform the function or action in association with other components in the printer. The process 400 is described as being performed with the printer 10′ of FIG. 1 for illustrative purposes.

The process 400 of operating the printer 10′ begins with the operation of the PWM unit to generate a 100% duty cycle signal to activate the printhead heater and raise the temperature of the printhead to the lower threshold of the two setpoints (block 404). Thereafter, the controller compares the temperature sensor signal to the two setpoint temperatures (block 408) and as long as the printhead temperature is within the temperature range defined by the two setpoints, the PWM unit is operated to adjust the PWM signal to keep the printhead temperature within the temperature range (block 412). When the printhead temperature signal indicates the printhead signal is outside the temperature range, it determines whether the printhead temperature exceeds the upper threshold (block 416). If it has, the PWM unit is operated to generate a PWM signal with a zero percent duty cycle and the current generator is operated to supply an electrical current to the thermoelectric cooling device (block 420). This processing (blocks 416 and 420) continues until the printhead temperature no longer exceeds the upper threshold. The process deactivates the current generator to turn off the cooling device (block 424) and the process determines if the printhead temperature is less than the lower temperature threshold (block 428). If it is, the PWM unit is operated to generate a PWM signal with a 100% duty cycle (block 404) and the process continues. If the printhead temperature does not exceed the upper threshold and it is not less than the lower threshold, the process verifies the printhead temperature is within the temperature range (block 408) and continues with the PWM signal adjustment until the temperature falls outside of the temperature range.

It will be appreciated that variants of the above-disclosed and other features, and functions, or alternatives thereof, may be desirably combined into many other different systems or applications. Various presently unforeseen or unanticipated alternatives, modifications, variations, or improvements therein may be subsequently made by those skilled in the art, which are also intended to be encompassed by the following claims.

What is claimed is:

1. An inkjet printer comprising:
a printhead configured to eject drops of ink;
a sensor configured to generate a signal indicative of a temperature of the printhead;
a first thermoelectric cooling device configured to remove heat from the printhead; and
a controller operatively connected to the sensor and the first cooling device, the controller being configured to:
operate the first cooling device to remove heat from the printhead in response to the signal generated by the sensor indicating the temperature of the printhead is greater than a predetermined temperature setpoint.

2. The inkjet printer of claim 1 further comprising:
a thermal conductive member mounted to the printhead to conduct heat from the printhead; and
the first thermoelectric cooling device being further configured to remove heat from the thermal conductive member.

3. The inkjet printer of claim 2 further comprising:
an electrical current generator operatively connected to the first thermoelectric cooling device; and
the controller being operatively connected to the electrical current generator, the controller being further configured to:
operate the electrical current generator to activate the first thermoelectric cooling device.

4. The inkjet printer of claim 3 wherein the thermoelectric cooling device is a peltier cooling device.

5. The inkjet printer of claim 4 further comprising:
a heat sink mounted to the peltier cooling device to dissipate heat from the peltier cooling device.

6. The inkjet printer of claim 5 wherein the thermal conductive member is made of cooper.

7. The inkjet printer of claim 6 wherein the heat sink is made of aluminum.

8. The inkjet printer of claim 7 further comprising:
a second thermoelectric cooling device that is mounted on a side of the printhead that is opposite a side of the printhead on which the first thermoelectric cooling device is mounted.

9. A method of operating an inkjet printer comprising:
generating a signal indicative of a temperature of a printhead in the inkjet printer;
comparing the generated signal to a predetermined temperature setpoint; and
operating a first thermoelectric cooling device to remove heat from the printhead in response to the signal generated by the sensor indicating the temperature of the printhead is greater than the predetermined temperature setpoint.

10. The method of claim 9 further comprising:
conducting heat from the printhead with a thermally conductive member; and
operating the first thermoelectric cooling device to remove heat from the thermally conductive member.

11. The method of claim 10 further comprising:
generating an electrical current; and
connecting the generated electrical current to the first thermoelectric cooling device to activate the first thermoelectric cooling device.

12. The method of claim 11 wherein the connecting of the generated electrical current to the first thermoelectric cooling device connects the generated electrical current to a peltier cooling device.

13. The method of claim 12 further comprising:
dissipating heat from the peltier cooling device with a heat sink mounted to the peltier cooling device.

14. The method of claim 13 wherein the thermal conductive member is made of cooper.

15. The method of claim 14 wherein the heat sink is made of aluminum.

16. The method of claim 15 further comprising:
cooling the printhead with a second thermoelectric cooling device that is mounted on a side of the printhead that is opposite a side of the printhead on which the first thermoelectric cooling device is mounted.

17. A thermal regulation module comprising:
a bracket;
a first thermal conductive member mounted to the bracket; and
a first thermoelectric cooling device mounted to the first thermal conductive member, the first thermoelectric cooling device being configured to remove heat from the first thermal conductive member.

18. The module of claim 17, the bracket being further configured with an opening that corresponds to a shape of a printhead.

19. The module of claim 18, the opening in the bracket being further configured to correspond to a width of a printhead in a process direction and a length of the printhead in a cross-process direction.

20. The module of claim 19, the bracket being further configured with a U-shape having two parallel sides that are configured to be adjacent opposite sides of the printhead.

21. The module of claim 20 wherein the first thermal conductive member is mounted to a first side of the bracket; and the module further comprising:
a second thermal conductive member to a second side of the bracket; and
a second thermoelectric conductive member mounted to the second thermal conductive member.

22. The module of claim 21 further comprising:
a first heat sink mounted to the first thermoelectric cooling device; and
a second heat sink mounted to the second thermoelectric cooling device.

23. The module of claim 22 wherein the first thermoelectric cooling device and the second thermoelectric device are peltier cooling devices.

24. The module of claim 23 wherein the first thermal conductive member and the second thermal conductive member are each made of cooper.

25. The module of claim 23 wherein the first thermal conductive member and the second thermal conductive member are each made of aluminum.

26. The module of claim 19, the bracket being further configured with a rectangular shape having two parallel sides that are configured to be adjacent opposite sides of the printhead in the process direction and two parallel sides that are configured to be adjacent opposite sides of the printhead in the cross-process direction.

27. The module of claim 22 wherein the first heat sink and the second heat sink are made of aluminum.

28. The module of claim 27 wherein the first heat sink and the second heat sink are a plurality of aluminum fins.

29. A printhead comprising:
a printhead having a plurality of inkjets, each inkjet being configured with a piezoelectric transducer to eject ink drops;
a thermal conductive member mounted to a first side of the printhead; and
a thermoelectric cooling device mounted to the thermal conductive member, the configured to remove heat from the thermal conductive member.

30. The printhead of claim 29 further comprising:
a heat sink mounted to the thermoelectric cooling device.

31. The printhead of claim 30 wherein the heat sink and the thermal conductive member are mounted on opposite sides of the thermoelectric cooling device.

32. The printhead of claim 31 wherein the thermoelectric cooling device is a peltier cooling device.
